(19) United States
(12) Patent Application Publication
(10) Pub. No.: US 2025/0165553 A1
(43) Pub. Date: May 22, 2025

(54) Fractional Resampler

(71) Applicant: NATIONAL INSTRUMENTS CORPORATION, Austin, TX (US)

(72) Inventor: Aljosa Vrancic, Austin, TX (US)

(21) Appl. No.: 18/514,448

(22) Filed: Nov. 20, 2023

(51) Int. Cl. G06F 17/14; H03H 17/02

(52) U.S. Cl. CPC G06F 17/142; H03H 17/0213

(57) ABSTRACT

Methods and systems for resampling an input signal that includes a first plurality of values. A first resampling is performed to obtain an intermediate signal, which includes dividing the first plurality of values into a plurality of groups of values, resampling values in each group according to a first filter tap set to obtain an intermediate group of values. The first value of each group is aligned in time with the first value of each intermediate group. A second resampling is then performed on the intermediate signal to obtain an output signal, which performs a phase shift of each of the intermediate groups of values to align in time with a respective group of values of the output signal. The output signal is output by wired or wireless means.

### FIELD OF THE INVENTION

The present invention relates to the field of signal analysis, and more particularly to a system and method for performing digital signal resampling.

### DESCRIPTION OF THE RELATED ART

A wide variety of technological applications perform digital resampling of signals to modify their sampling rate. Depending on the relationship between the input sampling rate and the output sampling rate, resampling may be a computationally intensive process that utilizes a large quantity of memory and/or processing resources to obtain a desired level of fidelity in the output signal. Accordingly, improvements in efficiency and precision for resampling methods are desired.

### SUMMARY OF THE INVENTION

Various embodiments of a system, computer program and method for resampling an input signal are described herein.

In some embodiments, an input signal is received that includes a first plurality of values x[tᵢ] for each of a plurality of respective times tᵢ.

In some embodiments, a first resampling of the input signal is performed to obtain an intermediate signal. The intermediate signal includes a second plurality of values y[tⱼ] for each of a plurality of respective times tⱼ. Performing the first resampling of the input signal may involve dividing the first plurality of values into a plurality of groups of values, and for each group, resampling values in the group according to a first filter tap set to an intermediate group of values. The first value of each group may be aligned in time with the first value of each intermediate group.

In some embodiments, a second resampling of the intermediate signal is performed to obtain an output signal that includes a third plurality of values z[tₖ] for each of a plurality of times tₖ. Performing the second resampling may include phase shifting each of the intermediate groups to align in time with a respective group of values of the output signal.

In some embodiments, the method concludes by outputting the output signal by a wired or wireless means.

### BRIEF DESCRIPTION OF THE DRAWINGS

A better understanding of the present invention can be obtained when the following detailed description of the preferred embodiment is considered in conjunction with the following drawings, in which:

FIG. 1 illustrates an exemplary computer system, according to various embodiments;

FIG. 2 illustrates components of a system configured to receive and process an input signal, according to some embodiments;

FIGS. 3A-B illustrate sampled points from an input sinusoidal signal, according to some embodiments;

FIGS. 4A-C illustrate filter tap values used for performing resampling, according to some embodiments;

FIG. 5 illustrates filter tap values for performing two-stage fractional resampling, according to some embodiments; and

FIG. 6 is a flowchart diagram illustrating a method for performing fractional resampling, according to some embodiments.

While the invention is susceptible to various modifications and alternative forms, specific embodiments thereof are shown by way of example in the drawings and are herein described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims.

### DETAILED DESCRIPTION OF THE INVENTION

### Terms

The following is a glossary of terms used in the present application:

Memory Medium-Any of various types of memory devices or storage devices. The term “memory medium” is intended to include an installation medium, e.g., a CD-ROM, floppy disks, or tape device; a computer system memory or random access memory such as DRAM, DDR RAM, SRAM, EDO RAM, Rambus RAM, etc.; a non-volatile memory such as a Flash, magnetic media, e.g., a hard drive, or optical storage; registers, or other similar types of memory elements, etc. The memory medium may comprise other types of memory as well or combinations thereof. In addition, the memory medium may be located in a first computer in which the programs are executed, or may be located in a second different computer which connects to the first computer over a network, such as the Internet. In the latter instance, the second computer may provide program instructions to the first computer for execution. The term “memory medium” may include two or more memory mediums which may reside in different locations, e.g., in different computers that are connected over a network.

Carrier Medium-a memory medium as described above, as well as a physical transmission medium, such as a bus, network, and/or other physical transmission medium that conveys signals such as electrical, electromagnetic, or digital signals.

Programmable Hardware Element-includes various hardware devices comprising multiple programmable function blocks connected via a programmable interconnect. Examples include FPGAs (Field Programmable Gate Arrays), PLDs (Programmable Logic Devices), FPOAs (Field Programmable Object Arrays), and CPLDs (Complex PLDs). The programmable function blocks may range from fine grained (combinatorial logic or look up tables) to coarse grained (arithmetic logic units or processor cores). A programmable hardware element may also be referred to as “reconfigurable logic”.

Software Program—the term “software program” is intended to have the full breadth of its ordinary meaning, and includes any type of program instructions, code, script and/or data, or combinations thereof, that may be stored in a memory medium and executed by a processor. Exemplary software programs include programs written in text-based programming languages, such as C, C++, PASCAL, FORTRAN, Python, JAVA, assembly language, etc.; graphical programs (programs written in graphical programming languages); assembly language programs; programs that have been compiled to machine language; scripts; and other types of executable software. A software program may comprise two or more software programs that interoperate in some manner. Note that various embodiments described herein may be implemented by a computer or software program. A software program may be stored as program instructions on a memory medium.

Hardware Configuration Program-a program, e.g., a netlist or bit file, that can be used to program or configure a programmable hardware element.

Program—the term “program” is intended to have the full breadth of its ordinary meaning. The term “program” includes 1) a software program which may be stored in a memory and is executable by a processor or 2) a hardware configuration program useable for configuring a programmable hardware element.

Graphical Program-A program comprising a plurality of interconnected nodes or icons, wherein the plurality of interconnected nodes or icons visually indicate functionality of the program. The interconnected nodes or icons are graphical source code for the program. Graphical function nodes may also be referred to as blocks.

The following provides examples of various aspects of graphical programs. The following examples and discussion are not intended to limit the above definition of graphical program, but rather provide examples of what the term “graphical program” encompasses:

The nodes in a graphical program may be connected in one or more of a data flow, control flow, and/or execution flow format. The nodes may also be connected in a “signal flow” format, which is a subset of data flow.

Exemplary graphical program development environments which may be used to create graphical programs include LabVIEW®, DasyLab™, DiaDem™ and Matrixx/SystemBuild™ from National Instruments, Simulink® from the MathWorks, VEE™ from Agilent, WiT™ from Coreco, Vision Program Manager™ from PPT Vision, SoftWIRE™ from Measurement Computing, Sanscript™ from Northwoods Software, Khoros™ from Khoral Research, SnapMaster™ from HEM Data, VisSim™ from Visual Solutions, ObjectBench™ by SES (Scientific and Engineering Software), and VisiDAQ™ from Advantech, among others.

The term “graphical program” includes models or block diagrams created in graphical modeling environments, wherein the model or block diagram comprises interconnected blocks (i.e., nodes) or icons that visually indicate operation of the model or block diagram; exemplary graphical modeling environments include Simulink®, SystemBuild™, VisSim™, Hypersignal Block Diagram™, etc.

A graphical program may be represented in the memory of the computer system as data structures and/or program instructions. The graphical program, e.g., these data structures and/or program instructions, may be compiled or interpreted to produce machine language that accomplishes the desired method or process as shown in the graphical program.

Input data to a graphical program may be received from any of various sources, such as from a device, unit under test, a process being measured or controlled, another computer program, a database, or from a file. Also, a user may input data to a graphical program or virtual instrument using a graphical user interface, e.g., a front panel.

A graphical program may optionally have a GUI associated with the graphical program. In this case, the plurality of interconnected blocks or nodes are often referred to as the block diagram portion of the graphical program.

Computer System-any of various types of computing or processing systems, including a personal computer system (PC), mainframe computer system, workstation, network appliance, Internet appliance, personal digital assistant (PDA), television system, grid computing system, or other device or combinations of devices. In general, the term “computer system” can be broadly defined to encompass any device (or combination of devices) having at least one processor that executes instructions from a memory medium.

Measurement Device-includes instruments, data acquisition devices, smart sensors, and any of various types of devices that are configured to acquire and/or store data. A measurement device may also optionally be further configured to analyze or process the acquired or stored data. Examples of a measurement device include an instrument, such as a traditional stand-alone “box” instrument, a computer-based instrument (instrument on a card) or external instrument, a data acquisition card, a device external to a computer that operates similarly to a data acquisition card, a smart sensor, one or more DAQ or measurement cards or modules in a chassis, an image acquisition device, such as an image acquisition (or machine vision) card (also called a video capture board) or smart camera, a motion control device, a robot having machine vision, and other similar types of devices. Exemplary “stand-alone” instruments include oscilloscopes, multimeters, signal analyzers, arbitrary waveform generators, spectroscopes, and similar measurement, test, or automation instruments.

A measurement device may be further configured to perform control functions, e.g., in response to analysis of the acquired or stored data. For example, the measurement device may send a control signal to an external system, such as a motion control system or to a sensor, in response to particular data. A measurement device may also be configured to perform automation functions, i.e., may receive and analyze data, and issue automation control signals in response.

Automatically-refers to an action or operation performed by a computer system (e.g., software executed by the computer system) or device (e.g., circuitry, programmable hardware elements, ASICs, etc.), without user input directly specifying or performing the action or operation. Thus the term “automatically” is in contrast to an operation being manually performed or specified by the user, where the user provides input to directly perform the operation. An automatic procedure may be initiated by input provided by the user, but the subsequent actions that are performed “automatically” are not specified by the user, i.e., are not performed “manually”, where the user specifies each action to perform. For example, a user filling out an electronic form by selecting each field and providing input specifying information (e.g., by typing information, selecting check boxes, radio selections, etc.) is filling out the form manually, even though the computer system must update the form in response to the user actions. The form may be automatically filled out by the computer system where the computer system (e.g., software executing on the computer system) analyzes the fields of the form and fills in the form without any user input specifying the answers to the fields. As indicated above, the user may invoke the automatic filling of the form, but is not involved in the actual filling of the form (e.g., the user is not manually specifying answers to fields but rather they are being automatically completed). The present specification provides various examples of operations being automatically performed in response to actions the user has taken.

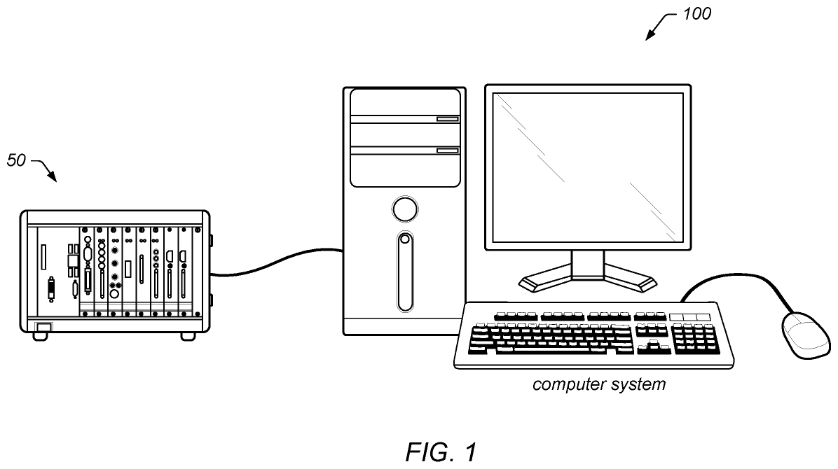

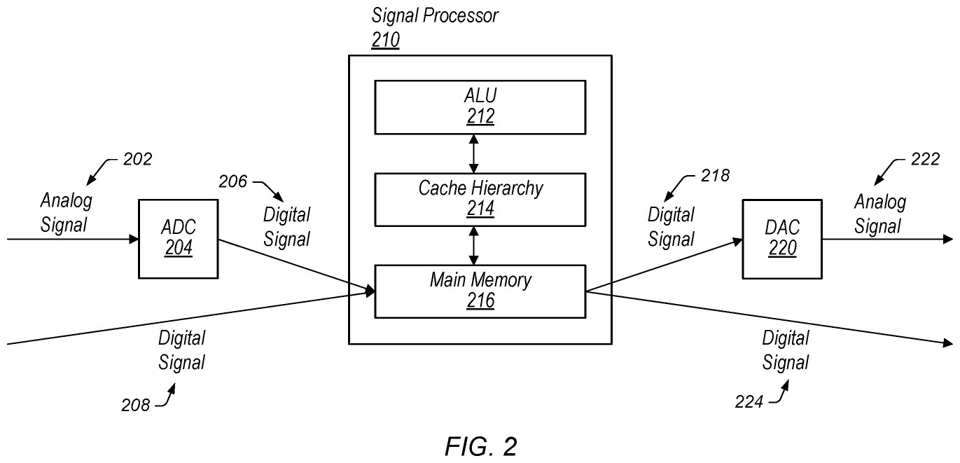

### FIG. 1-2-Exemplary Systems

FIG. 1 illustrates an exemplary system which may implement embodiments described herein. The system may be configured to receive an input signal from a device-under-test (DUT) or a system-under-test (SUT), resample the input signal to a new sampling frequency, and output the resampled signal. As shown in FIG. 1, an exemplary chassis 50 is coupled to a computer system 100. The chassis 50 and/or the computer system 100 may each contain one or more components used to perform embodiments described herein, e.g., an analog-to-digital converter (ADC), a digital-to-analog converter (DAC), input ports, output ports, processor(s), and non-transitory memory media. The system may be configured to receive an input analog signal and output a resampled output analog signal, in some embodiments. In some embodiments, the chassis may be directly coupled to a device that produces the input analog signal, whereas the computer system may contain the processor(s) and/or memory to perform the resampling process. The resampled signal may then be provided back to the chassis, in at least some embodiments. The ADC and DAC may be contained in either the chassis (e.g., so that the chassis provides the input digital signal to and receives the resampled digital signal from the computer system) or the computer system (e.g., so that the chassis provides the input analog signal to and receives the analog resampled output signal from the computer system), according to various embodiments.

The chassis 50 may include a host device (e.g., a host controller board), which may include a CPU, memory, and chipset. Other functions that may be found on the host device are represented by the miscellaneous functions block. In some embodiments, the host device may include a processor and memory (as shown) and/or may include a programmable hardware element (e.g., a field programmable gate array (FPGA)). Additionally, one or more of the cards or devices may also include a programmable hardware element. In further embodiments, a backplane of the chassis 50 may include a programmable hardware element. In embodiments including a programmable hardware element, it may be configured according to a graphical program.

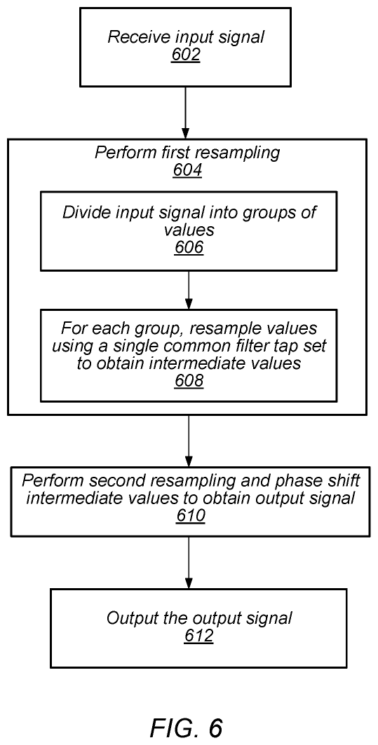

FIG. 2 is a system diagram illustrating a system configured to perform resampling, according to some embodiments. As illustrated, an input analog signal 202 may be received by an analog-to-digital converter (ADC) 204, which converts the input signal to a digital signal 206. The digital signal 206 may then be provided to a signal processor 210. The ADC converts the input analog signal to a discrete digital signal with a particular sampling rate or frequency. Alternatively or additionally, a digital signal 208 may be directly received by a DUT or SUT (e.g., from a DUT or SUT that is being simulated in the digital domain), bypassing the ADC 204. The discrete digital signal 206 or 208 may serve as the input signal for the method described in FIG. 6, for example. The signal processor 210 may include an arithmetic logic unit (ALU) 212, a cache hierarchy 214, and main memory 216 that are configured to process the input digital signals to produce a resampled digital signal. The resampled digital signal may have a different sampling rate from the input digital signal, and may be resampled according to embodiments described herein. The resampled digital signal may be identified as the output signal in the method described in FIG. 6, in some embodiments. This resampled digital signal may be output to a digital-to-analog converter (DAC) 220, which converts the resampled digital signal 218 to an output analog signal 222. Alternatively or additionally, the resampled digital signal 224 may be output directly in the digital domain, bypassing the DAC 220.

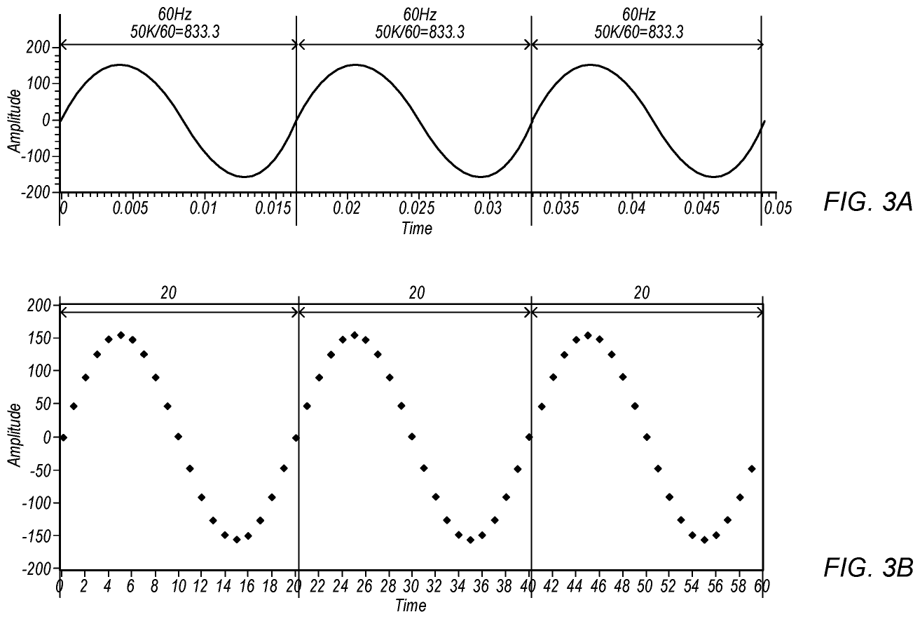

### FIGS. 3A and 3B-Exemplary Signals Before and After Processing

FIGS. 3A and 3B illustrate exemplary signals before and after processing, where FIG. 3A shows and input analog signal and FIG. 3B shows the digital signal output by the ADC. FIG. 3A illustrates an exemplary signal where, before resampling, the signal includes a constant cycle at 60 Hz.

As shown in FIG. 3B, after resampling, 20 samples per cycle are shown for exemplary purposes only; however, a more common sampling rate would be 128 samples per cycle.

### Fractional Resampling

Resampling describes various methods whereby a discrete input signal is received and processed to output an output signal with a different sampling rate and/or a phase shift. Fractional resampling may be described in terms of a ratio of two integers M/N, where M and N have a highest common factor of 1, M indicates that that the resampling will insert M-1 new equally spaced samples in between any two input samples (i.e., the input signal may be upsampled M times) and the number N indicates that only every Nth sample of the upsampled signal will be kept (i.e., the upsampled signal may then be downsampled by N). An M/N fractional resampling may utilize M different filter-tap sets. Filter taps are values that the input signal is multiplied by before the results of the multiplication are summed up to obtain the output sample, and they encode in their values desired filter characteristics such as cutoff frequency, pass-band width, pass band ripple, stop band width, stop band rejection, etc. As M grows larger, the amount of memory utilized to store the filter data may become too large to fit into memories/caches that are closest to the processing units (for example, L1 cache in CPUs, GPUs, and vectorized coprocessors such as Xilinx AI Engines), resulting in increased latency and decreased computational bandwidth. An alternative approach is to choose a subset of I filter-tap sets such that they fit into the lowest level cache and then use interpolation techniques to compute resampled values that fall in between output phases corresponding to the I offsets. Embodiments herein replace a single pass filtering into a two-pass filtering for which the number of filter-tap sets may be chosen in advance and does not change with the value of M. Advantageously, the described embodiments may allow filter data to fully reside in the memory closest to the processing unit (e.g., L1 cache) while also eliminating the interpolation step that both increases the amount of computation and may introduce errors.

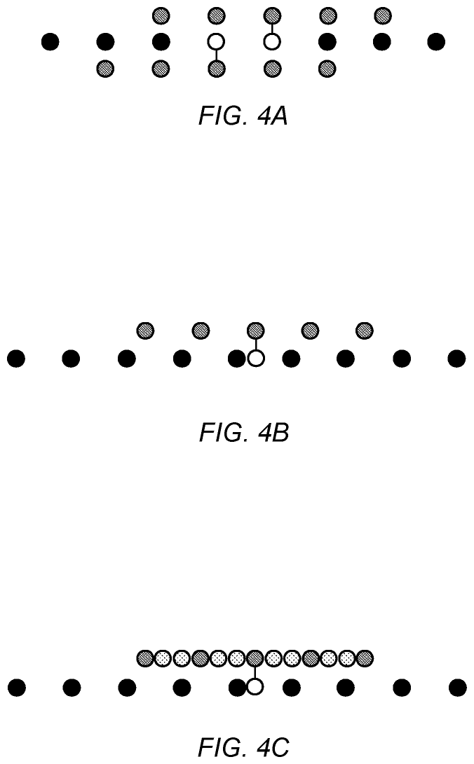

Filtering in the time domain may consist of convolution of filter taps F [j] (N_{T}=number of taps) with the input signal x[i] as shown in FIG. 4A for an N_{T}=5. The illustrated circles in the middle row (both black and white circles) represent input data, and the shaded grey circles in the rows above and below represent filter taps. The white circles represent the input data points that correspond to the two sets of filter taps. The vertical lines indicate for which input point the filtered value is being calculated, i.e., the point is collocated with the middle filter tap.

Mathematically, the i-th point on the filter output y[i] may be computed as

$$y [ i ] = {\sum }_{j = 0}^{{N}_{T} - 1} x [ i + j - {N}_{T} / 2 ] * F [ j ] \qquad ( 1 )$$

The resampling process may become more complicated when a signal is to be phase shifted in addition to applying a filter. For example, let's assume that we would like to compute the output value corresponding to the unshaded point shown in FIG. 4B (which is not present in the input data, represented by black circles).

Following the rule above, the new point may be obtained by centering the filter taps at the given location and multiplying the values with the corresponding input signal. Unfortunately, the problem with this approach is that in this case the taps align with unknown parts of the input signal that are being calculated in the first place. A solution is to “up-sample” the input signal by placing extra points in-between the existing points, generate a corresponding number of additional taps for the filter, and then perform the convolution as shown in FIG. 4C for the case of up-sampling by a factor of 3. The original five filter taps are shown with dark grey shading, the additional filter taps are shown in light shading, and Os in the input signal are not shown for simplicity.

Even though the number of taps went up by 3×, the number of multiplies stays the same (or may be reduced by 1) because only one out of every three input samples is nonzero for a corresponding filter tap value. In general, the up-sample factor may depend directly on the phase shift. In the example shown in FIG. 4C, a phase shift of ⅓ of the input sampling frequency resulted in the up-sampling factor of 3. Now consider the case where the target phase shift is 0.9786542. There are several approaches possible to performing resampling with this phase shift. As a first possibility, Option (i), the filter taps may be up-sampled by a factor of 10,000,000, the filter taps may be computed that line up with the non-zero input points (there will be 4) and the 4-point convolution may be performed. As a second possibility, Option (ii), relevant filter taps may be computed for phases 0.978 and 0.979, and linear interpolation may be used between the taps to obtain the final tap values. As a third possibility, Option (iii), the output point values for phase shifts of 0.978 and 0.979 may be computed, and linear interpolation may be performed between these two values to obtain the target value. Mathematically, Options (ii) and (iii) are identical but (ii) utilizes more computation since N_{T} points are being interpolated instead of only one. However, despite the difference in the number of operations, current FPGA implementations typically use Option (ii) because it is more efficient. For the filtering/phase-shift case only, the first approach is the best: every output point is located at the same phase shift with respect to the input points, so the relevant filter taps may be computed exactly upfront, resulting in an optimal error since no interpolation is performed.

In some embodiments, fractional resampling may be employed, which may be described by a ratio of two integers M/N for which there are exactly M different time offsets between two input samples. For approach (i) above, that implies that there will be M different sets of filter taps. As M grows larger, the most efficient memories that are close to the processing units may become overwhelmed and the filtering throughput may drop as memories further and further away are used to store the filter tap values. For example, a compute unit may have only 32 KB of L1 cache that can be accessed in one clock cycle. Accessing data from L2, L3, etc., or the main memory may introduce latencies on the order of 100 ns. The latency is important because the M filter-tap sets are not accessed in a fixed order. Instead, the access may be random or pseudorandom such that every time a block of taps that is not in the L1 is to be used, the data may be brought from a memory further away resulting in additional latency that limits the processing throughput as the processing units idle while waiting for the data. In addition to having higher latencies, “further” memories also have lower data throughput. For example, a data throughput from a main memory may be 20× lower than that from an L1 cache. Furthermore, the main memory bandwidth may be typically shared between the processing cores so employing multiple cores to speed up the computation may work only if taps are stored in memory that scales with the number of cores, i.e., typically L1 & L2 caches. Spinning up more cores may not help since the maximum processing bandwidth of a single core is already more than the main memory can handle. Accordingly, adding additional ones that have to share the memory bandwidth may not only fail to result in speedup but may actually cause slowdowns as the memory access arbitrator has more work to do.

Therefore, for computation architectures that heavily depend on the close-by caches for efficient computation (for example, Xilinx AI Engines, vectorized CPU cores, GPUs, etc.), having a limited number of filter-tap sets or, even better, having a fixed set of filter-taps may result in significant speedup. This may particularly be the case when the taps fit into registers or caches that are local to a set of computation units, so that the memory bandwidth scales with the number of compute units. Options (ii) and (iii) above allow having a limited number of taps, and the number of taps may be equal to the number of points used for the interpolation. The number of interpolation points may depend on the maximum desired error (for output offsets that fall exactly halfway in the interpolation interval) and may be independent of the value of M. Interpolation may increase error in the output signal, increase the number of computational steps, result in higher data throughput because more data enters the processing unit for each output point (registers may not be used for continuously changing tap data), and lower the efficiency of the vectorization algorithm when accessing filter taps in a random-like fashion. In terms of the computation cost, a resampling with an N_{T}-tap filter may in general utilize approximately 2N_{T} computations for Option (iii), N_{T} for each of the two points and a few operations to compute the offsets for the two sets of taps. In addition, it utilizes random-like access to the filter data which impacts efficiency of the vectorization. Option (ii) utilizes about 3N_{T} computations, slightly more because of more interpolation steps.

Embodiments described herein divide input points into groups and uses two different filters, one of which has a fixed number of filter-taps equal to the group length, and the second one that has fixed taps recomputed only once per group and may thus be stored inside the registers for smaller filter lengths. In addition, in some embodiments the method avoids performing interpolation, so the only source of error may be due to the final filter length.

As one specific example, a 31-tap filter may be used to resample input signal, wherein a resampling factor of 0.98765 will utilize 100,000 31-tap filter sets when using Option (i). This may not fit in a typical L1 cache, and each output point may involve only 31 multiply-and-accumulate operations. In contrast, embodiments herein using two-stage resampling with a group size of 512 will utilize only 512 31-tap filter sets, with only one new 31-tap filter set computed for each new group resulting in approximately 2*31*(512+30)/512+2*31/512 multiply-and-accumulate operations per output point. Compared to Option (i), this results in an approximately 25% increase in the utilized computation resources while increasing throughput by several times because all of the taps may fit into the L1 cache and/or registers.

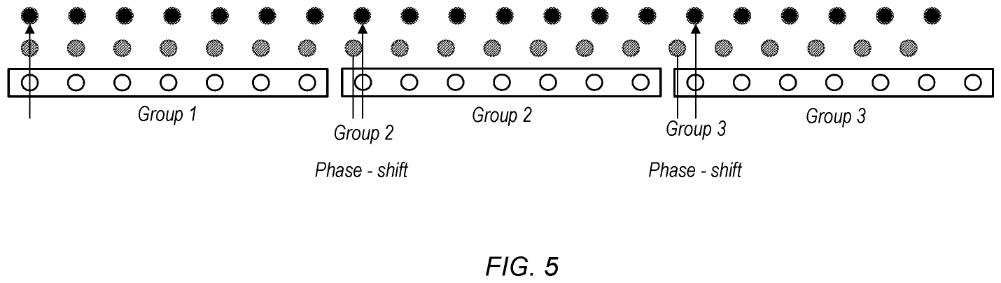

FIG. 5 illustrates operation of the two-stage filter. The input samples are shown as black circles, and the horizontal axis represents time. The output of the filter produces samples located in time shown by shaded grey circles. The input points are divided into groups of N samples and the desired resample filter has N_{T} taps. The actual expression above is reconstructed using N=512 and N_{T}=31. In the first phase of the two-stage resampling, for each group of N input points, a corresponding group of intermediate points shown as white (unshaded) circles is computed using group-independent-per-point fixed filter-tap sets-31 multiply-and-accumulate operations (MACs) for each point, and 512 different filter-tap sets. Since the intermediate points are separated in time by the same amount as the desired output points, the correct output values may be obtained by phase-shifting the intermediate points in each group by a fixed amount. Consequently, all final output points computed from one intermediate group are obtained using the same phase-shift filter-tap set as described above-31 MACs per point. Each group may be shifted by a different phase so new filter taps may be recalculated for each new group of points, i.e., 2*31 MACs for each group, or 2*31/512 on average per point. Because of the second filter pass, additional N_{T}/2 edge points are utilized on each side of a group, so an additional 30/512 operations are utilized per group resulting in the (512+30)/512 factor in the above expression. The final general expression for the number of MACs is:

$$2 * {N}_{T} * [ N + 2 * ( {N}_{T} / 2 ) ] / N + 2 * {N}_{T} / N$$

In some embodiments, the second pass already operates on bandwidth-limited signal (bandwidth is controlled by the first-pass filter) so the second pass filter may be made smaller (fewer taps) and the extra computation may be transferred to the first-pass filter by increasing its number of taps while still maintaining the overall number of taps equal to 2N_{T}.

### Cache Access Parameters

L1 is typically accessed in 1 clock cycle. Random and sequential access may have the same or similar throughput. Throughput may be on the order of terabytes per second (TB/s) for each core. Size is typically 32 or 64 kilobytes (KB). For all the other cache levels and the main memory, the sequential access may be much faster as the hardware automatically performs pre-fetching. In other words, it may assume sequential access and automatically issue reads from subsequent cache lines. L2 is typically accessed in 3-5 clock cycles, and throughput is ˜250 MB/s for each core if L2 is not shared. The L2 size is typically up to 1 megabyte (MB). L3 is typically accessed in 10-15 clock cycles, and throughput may depend on the number of active cores but is usually limited to ˜150 gigabytes per second (GB/s). The L3 size is typically up to 500 MB. Finally, main memory may have latencies of over 100 clock cycles. Throughput may depend on the number of memory channels and is typically less than 200 GB/s unless high bandwidth memory (HBM) is used.

Resampling generally involves two major components that determine performance, the amount of data that is brought into the CPU and the amount of computation involved to compute each output point. These two components are referred to herein as the algorithm memory and computation complexity, respectively. For example, a multiplication of a 32-bit floating point vector (array) by a constant involves one multiplication and one stored value. Accordingly, the ratio between memory and computation complexity is 1:1. Since modern processors may typically execute hundreds of giga-FLOPS but typically only have tens of GB/s throughput to main memory, this algorithm will be bound by the memory throughput unless the data is able to fit into the L1 cache. Conversely, a multiplication of two matrices is on the other end of the spectrum. In matrix multiplication, stored values may be reused for multiple computations, and the algorithm therefore has better memory utilization and may be limited by computation throughput more than memory storage.

Examples of basic computations performed by CPUs include addition, multiplication, and multiply-accumulate operations (MACs). Typically, these basic computations have similar latencies so that (a+b+c)/(a*b*c) will typically take longer to compute (e.g., two additions divided by two multiplications) compared to a*b+c (a single MAC).

For Options (i)-(iii) of resampling methodologies described above, the input values are reused multiple times (e.g., each value x[i] is reused 30 or 31 times for a 31-tap filter) so their contribution to the algorithm memory load is negligible when compared to the throughput to load the filter taps. The memory specifications for each option are as follows. Option (i) utilizes 31 tap values per point and 31 MACs. Accordingly, performance may be limited by the amount of memory used for different tap sets, which determines if the taps will be brought in from L1, L2, L3 or main memory. Option (ii) utilizes 62 tap values per point and ˜155 FLOPs/MACs. This is generally better than Option (i) since the interpolation enables a smaller number of tap sets to be situated closer to the compute units and also has a better balance between memory and computation resources of 1:2. Option (iii) utilizes 62 tap values per point and ˜65 FLOPs/MACs, which is better than (i) for the same reasons as (ii), and better than (ii) on a central processing unit (CPU) because of a smaller number of utilized FLOPs/MACs. However, if the performance is gated by the memory throughput because the tap values are stored in L2 or higher, (ii) and (iii) may have almost the same performance since higher latency allows for more computational steps per unit of data.

In some embodiments, filtering may be treated as a convolution when the filter taps do not change between the output points. Using only MAC operations, computation complexity of the algorithm grows as O(N*N_{T}) where N is the number of points and N_{T} is the number of taps per set. In some embodiments, for longer filters, a fast Fourier transform (FFT) may be used for performing convolution. Using an FFT may be desirable, as the computation complexity grows as O(M*lg(M)), where Mis max (N, N_{T}). In contrast, for Options (i) and (iii) new tap sets are used for each output point so that FFT may not be used.

For some described embodiments, the number of tap sets may be determined by the number of points in each group and may be typically selected to not be larger than 512. The tap set for the second stage may be the same for all points. Even though the second-stage taps utilize more computation, the overhead is equivalent to computing a single output point in (i)-(iii) so it will be spread over the number of output points computed in the second-step, i.e., it will be negligible (<3%) for 32+ points. Furthermore, one may use an FFT for computing the convolution for longer filters.

Embodiments herein may be desirable when the number of tap-sets in Option (iii) becomes too big for L1, since the number of sets in the first-stage group may be kept fixed (<512) regardless of the accuracy requirements (i.e., because the group size may be selected such that the tap data will fit into the L1 cache). Furthermore, for longer filter lengths, an FFT may be used to further speed up computation of the second stage. The intermediate results produced by stage 1 are stored in L1 so they do not significantly contribute to the memory throughput load on the processor. Finally, even when the tap data does not fit into L1, described embodiments may perform better than Options (i)-(iii) because the tap data for the first step is always the same and thus may be stored in sequential locations. Accordingly, the tap data may be accessed with a higher throughput compared to (i) and (iii), which access tap data in a random fashion.

### FIG. 6-Flowchart for Fractional Resampling

FIG. 6 illustrates a method for resampling on an input signal, according to some embodiments. The method shown in FIG. 6 may be used in conjunction with any of the computer systems or devices shown in the above Figures, among other devices. In various embodiments, some of the method elements shown may be performed concurrently, in a different order than shown, or may be omitted. Additional method elements may also be performed as desired. As shown, this method may operate as follows.

In 602, an input signal is received. The input signal may be a digital signal that includes a first plurality of values x[tᵢ] for each of a plurality of respective times tᵢ. The values x[tᵢ] may be regularly spaced in time with a fixed frequency. In some embodiments, an analog input signal is received by an analog-to-digital converter, which processes the analog input signal to produce the (digital) input signal.

At 604, a first resampling of the input signal is performed to obtain an intermediate signal that includes a second plurality of values y[tⱼ] for each of a plurality of respective times tⱼ. In some embodiments, the spacing in time of the values x[tᵢ] may be different from the spacing of the values y[tⱼ]. In other words, the first resampling may shift the frequency of the input signal to produce an intermediate signal with values having an altered frequency.

At 606, in some embodiments, to perform the first resampling, the first plurality of values of the input signal is divided into a plurality of groups, with each group including multiple values. In some embodiments, each group has the same number of values, or alternatively the groups may have different numbers of values. In some embodiments, the groups have approximately the same number of values, but depending on the ratio M/N of the fractional resampling, rounding may result in some groups having one more or one fewer value than other groups. In some embodiments, the number of values in the groups (or the average number of values for the groups) may be selected based at least in part on a size of the L1 memory cache, e.g., to avoid exceeding the size of the L1 memory cache while performing the first resampling.

At 608, for each of the groups, input signal values in the group may be resampled according to first filter tap sets to a group of intermediate values y[tⱼ]. In some embodiments, a first value of each group is aligned in time with a first value of the respective group of intermediate values. The “first” values may be the initial values of the group and the intermediate group, or alternatively they may be any arbitrary value (e.g., the second value, the third value, etc., as long as they are the same for both the group and the intermediate group). The set of groups of intermediate values may collectively comprise the intermediate signal.

The first resampling may include determining a respective set of filter taps for each value in a group, so that each value in the group has its own respective set of filter taps. The same sets of filter taps may be used to perform the first resampling for each of the plurality of groups. For example, with reference to FIG. 5, each of the seven intermediate values in Group 1 may have its own set of filter taps, but these same sets of filter taps may likewise be used for the intermediate values in Groups 2 and 3. For example, the first intermediate values in each group may each use the same set of filter taps, likewise the second intermediate values in each group may each use the same set of filter taps, and so on. This may reduce the computational complexity of the first resampling, by reducing number of sets of filter taps that are computed. In some embodiments, the number of filter taps of the sets of filter taps, N_{T}, may be selected based at least in part on a size of the L1 memory cache, e.g., so that the filter tap set size doesn't exceed the size of the L1 memory cache.

At 610, a second resampling of the intermediate signal is performed to obtain an output signal that includes a third plurality of values z[tₖ] for each of a plurality of times tₖ. The second resampling may be performed on a per-group basis, where the second resampling phase-shifts each group of intermediate values by a particular amount. For example, in reference to the example shown in FIG. 5, Group 1 may not be shifted at all because the intermediate values are already aligned with the output signal values. Each intermediate value in Group 2 will be phase-shifted by a particular amount to align the intermediate values with the output signal values. The Group 3 intermediate signal values may be shifted by twice this amount, and so on.

The second resampling may leave frequency unchanged (in contrast to the first resampling), so that time values tₖ of z[tₖ] and the time values tⱼ of y[tⱼ] are be separated by the same amount within each group. In other words, the second resampling may not alter the spacing between sequential values, but rather shifts the values in time without altering their spacing. The second resampling of the intermediate signal may involve phase shifting each of the intermediate groups to align in time with a respective group of values of the output signal.

The second resampling may include determining a respective set of filter taps for each respective intermediate group, and the same set of filter taps may be used for performing the second resampling of each value within a given group. In other words, in contrast to the first resampling (where each value has a unique set of filter taps, but these sets of filter taps are reused for each group), for the second resampling each value uses the same set of filter taps, but there is a different set of filter taps used for each group.

In some embodiments, the second resampling of the intermediate signal includes performing convolution on the intermediate signal values with a fast Fourier transform (FFT) using a set of filter taps.

In some embodiments, performing the second resampling of the intermediate signal includes performing spline interpolation between sets of values on either side of respective values of the third plurality of values z[tₖ]. Spline interpolation may provide a higher accuracy and introduce less error than using linear interpolation.

At 612, the output signal is output by a wired or wireless means. The output signal may be output to a digital-to-analog converter (DAC), which converts the (digital) output signal to an analog output signal, in some embodiments.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A method for resampling an input signal, the method comprising:
receiving the input signal, wherein the input signal comprises a first plurality of values x[tᵢ] for each of a plurality of respective times tᵢ;
performing a first resampling of the input signal to obtain an intermediate signal comprising a second plurality of values y[tⱼ] for each of a plurality of respective times tᵢ, wherein performing the first resampling of the input signal comprises:
dividing the first plurality of values into a plurality of groups, wherein each group comprises a plurality of respective values;
for each group of the plurality of groups, resampling values in the respective group according to a first filter tap set to a respective intermediate group of values, wherein a first value of the respective group is aligned in time with a first value of the respective intermediate group, wherein the intermediate signal comprises each of the intermediate groups of values;
performing a second resampling of the intermediate signal to obtain an output signal comprising a third plurality of values z[tₖ] for each of a plurality of times tₖ, wherein performing the second resampling of the intermediate signal comprises phase shifting each of the intermediate groups to align in time with a respective group of values of the output signal; and
outputting the output signal.

2. The method of claim 1,
wherein sequential values of the first plurality of values x[tᵢ] are separated in time by a first amount; and
wherein sequential values of the second plurality of values y[tᵢ] and the third plurality of values z[tₖ] are separated in time by a second amount different than the first amount.

3. The method of claim 1,
wherein performing the second resampling of the intermediate signal comprises determining a respective set of filter taps for each respective intermediate group, and
wherein a same set of filter taps is used for performing the second resampling of each value within a given group.

4. The method of claim 1,
wherein performing the first resampling of the input signal comprises:
for each of the plurality of values in a first group of the plurality of groups:
determining a respective set of filter taps; and
performing the first resampling using the determined sets of filter taps for each of the plurality of groups.

5. The method of claim 1, further comprising:
based at least in part on a size of an L1 memory cache, selecting one or more of:
a number of filter taps of the first filter tap set; and
a size of each group of the plurality of groups.

6. The method of claim 1,
wherein performing the second resampling of the intermediate signal comprises performing convolution on the intermediate signal values with a fast Fourier transform (FFT) using a set of filter taps.

7. The method of claim 1,
wherein performing the second resampling of the intermediate signal comprises performing spline interpolation between sets of values on either side of respective values of the third plurality of values z[tₖ].

8. The method of claim 1, further comprising:
receiving an analog input signal; and
processing the analog input signal by an analog-to-digital converter (ADC) to produce the input signal,
wherein outputting the output signal comprises providing the output signal to a digital-to-analog converter (DAC) to produce an output analog signal.

9. A non-transitory computer-readable memory medium storing program instructions, wherein the program instructions are executable by a processor to cause the processor to:
receive an input signal, wherein the input signal comprises a first plurality of values x[tᵢ] for each of a plurality of respective times tᵢ;
perform a first resampling of the input signal to obtain an intermediate signal comprising a second plurality of values y for each of a plurality of respective times tⱼ, wherein in performing the first resampling of the input signal, the program instructions are executable to cause the processor to:
divide the first plurality of values into a plurality of groups, wherein each group comprises a plurality of respective values;
for each group of the plurality of groups, resample values in the respective group according to a first filter tap set to a respective intermediate group of values, wherein a first value of the respective group is aligned in time with a first value of the respective intermediate group, wherein the intermediate signal comprises each of the intermediate groups of values;
perform a second resampling of the intermediate signal to obtain an output signal comprising a third plurality of values z[tₖ] for each of a plurality of times tₖ, wherein in performing the second resampling of the intermediate signal, the program instructions are executable to cause the processor to phase shift each of the intermediate groups to align in time with a respective group of values of the output signal; and
output the output signal.

10. The non-transitory computer-readable memory medium of claim 9,
wherein sequential values of the first plurality of values x[tᵢ] are separated in time by a first amount; and
wherein sequential values of the second plurality of values y[tᵢ] and the third plurality of values z[tₖ] are separated in time by a second amount different than the first amount.

11. The non-transitory computer-readable memory medium of claim 9,
wherein, in performing the second resampling of the intermediate signal, the program instructions are further executable to cause the processor to determine a respective set of filter taps for each respective intermediate group,
wherein a same set of filter taps is used for performing the second resampling of each value within a given group.

12. The non-transitory computer-readable memory medium of claim 9,
wherein, in performing the first resampling of the input signal, the program instructions are further executable to cause the processor to:
for each of the plurality of values in a first group of the plurality of groups:
determine a respective set of filter taps; and
perform the first resampling using the determined sets of filter taps for each of the plurality of groups.

13. The non-transitory computer-readable memory medium of claim 9, wherein the program instructions are further executable to cause the processor to:
based at least in part on a size of an L1 memory cache, select one or more of:
a number of filter taps of the first filter tap set; and
a size of each group of the plurality of groups.

14. The non-transitory computer-readable memory medium of claim 9,
wherein, in performing the second resampling of the intermediate signal, the program instructions are further executable to cause the processor to perform convolution on the intermediate signal values with a fast Fourier transform (FFT) using a set of filter taps.

15. The non-transitory computer-readable memory medium of claim 9,
wherein, in performing the second resampling of the intermediate signal, the program instructions are further executable to cause the processor to perform spline interpolation between sets of values on either side of respective values of the third plurality of values z[tₖ].

16. The non-transitory computer-readable memory medium of claim 9, wherein the program instructions are further executable to cause the processor to:
receive an analog input signal; and
process the analog input signal by an analog-to-digital converter (ADC) to produce the input signal; and
output the output signal to a digital-to-analog converter (DAC) to produce an output analog signal.

17. A digital signal resampling device, comprising:
an input port configured to receive an input signal, wherein the input signal comprises a first plurality of values x[tᵢ] for each of a plurality of respective times tᵢ;
a non-transitory computer-readable memory medium storing program instructions;
a processor coupled to the non-transitory computer-readable memory medium, wherein the processor is configured to execute the program instructions to:
perform a first resampling of the input signal to obtain an intermediate signal comprising a second plurality of values y for each of a plurality of respective times tⱼ, wherein in performing the first resampling of the input signal, the program instructions are executable to cause the processor to:
divide the first plurality of values into a plurality of groups, wherein each group comprises a plurality of respective values; and
for each group of the plurality of groups, resample values in the respective group according to a first filter tap set to a respective intermediate group of values, wherein a first value of the respective group is aligned in time with a first value of the respective intermediate group, wherein the intermediate signal comprises each of the intermediate groups of values; and
perform a second resampling of the intermediate signal to obtain an output signal comprising a third plurality of values z[tₖ] for each of a plurality of times tₖ, wherein in performing the second resampling of the intermediate signal, the program instructions are executable to cause the processor to phase shift each of the intermediate groups to align in time with a respective group of values of the output signal; and
an output port configured to output the output signal.

18. The digital signal resampling device of claim 17,
wherein sequential values of the first plurality of values x[tᵢ] are separated in time by a first amount; and
wherein sequential values of the second plurality of values y[tᵢ] and the third plurality of values z[tₖ] are separated in time by a second amount different than the first amount.

19. The digital signal resampling device of claim 17, wherein the program instructions are further executable to cause the processor to:
based at least in part on a size of an L1 memory cache of the memory medium, select one or more of:
a number of filter taps of the first filter tap set; and
a size of each group of the plurality of groups.

20. The digital signal resampling device of claim 17, further comprising:
an analog-to-digital converter (ADC) configured to receive an analog input signal, wherein the ADC is configured to process the analog input signal to produce the input signal; and
a digital-to-analog converter (DAC) configured to receive the output signal, wherein the DAC is configured to process the output signal to produce an output analog signal.
